(19) United States
(12) Patent Application Publication
(10) Pub. No.: US 2012/0068214 A1
(43) Pub. Date: Mar. 22, 2012

(54) OPTOELECTRONIC DEVICE AND METHOD FOR MANUFACTURING THE SAME

(75) Inventors: De-Shan Kuo, Hsinchu (TW); Ting-Chia Ko, Hsinchu (TW); Tsun-Kai Ko, Hsinchu (TW)

(73) Assignee: Epistar Corporation, Hsinchu (TW)

(21) Appl. No.: 13/235,797

(22) Filed: Sep. 19, 2011

(30) Foreign Application Priority Data
Sep. 21, 2010 (TW) 099132135

(51) Int. Cl. H01L 33/20; H01L 21/302

(52) U.S. Cl. 257/98; 438/32; 257/E33.068; 257/E21.214

(57) ABSTRACT

An optoelectronic device is provided that includes a substrate having a surface and a normal direction perpendicular to the surface, a first semiconductor layer formed on the surface, and at least one hollow component formed between the first semiconductor layer and the surface. A method of fabricating an optoelectronic device is also provided that includes providing a substrate having a surface and a normal direction perpendicular to the surface, forming a first semiconductor layer on the surface, patterning the first semiconductor layer, forming a second semiconductor layer on the substrate and cover the patterned first semiconductor layer, and forming at least one hollow component formed between the first semiconductor layer and the surface. A height of the hollow component varies along with a first direction perpendicular to the normal direction and/or a width of the hollow component varies along with a second direction parallel with the normal direction.

### RELATED APPLICATION

This application claims the priority to and the benefit of TW application Ser. No. 099132135 filed on Sep. 21, 2010 wherein the contents of which are incorporated herein by reference in their entirety.

### BACKGROUND

1. Technical Field

The present disclosure relates to an optoelectronic device having a hollow component formed between the semiconductor layer and the substrate.

2. Description of the Related Art

The light radiation theory of light emitting diode (LED) is to generate light from the energy released by the electron moving between the n-type semiconductor and the p-type semiconductor. Because the light radiation theory of LED is different from the incandescent light which heats the filament, the LED is called a “cold” light source.

Moreover, the LED is more sustainable, longevous, light and handy, and less power consumption, therefore it is considered as a new light source for the illumination markets. The LED applies to various applications like the traffic signal, backlight module, street light, and medical instruments, and is gradually replacing the traditional lighting sources.

### SUMMARY OF THE DISCLOSURE

An optoelectronic device comprising: a substrate having a surface and a normal direction perpendicular to the surface; a first semiconductor layer formed on the surface of the substrate; and at least one hollow component formed between the first semiconductor layer and the surface of the substrate wherein a height of the hollow component varies along with a first direction perpendicular to the normal direction and/or a width of the hollow component varies along with a second direction parallel with the normal direction.

A method of fabricating an optoelectronic device comprising: providing a substrate having a surface and a normal direction perpendicular to the surface; forming a first semiconductor layer on the surface of the substrate; patterning the first semiconductor layer; forming a second semiconductor layer on the substrate and cover the patterned first semiconductor layer; and forming at least one hollow component formed between the first semiconductor layer and the surface of the substrate wherein a height of the hollow component varies along with a first direction perpendicular to the normal direction and/or a width of the hollow component varies along with a second direction parallel with the normal direction.

### BRIEF DESCRIPTION OF DRAWINGS

The accompanying drawings are included to provide easy understanding of the application, and are incorporated herein and constitute a part of this specification. The drawings illustrate embodiments of the application and, together with the description, serve to illustrate the principles of the application.

FIGS. 1A-1F illustrate a process flow of a method of fabricating an optoelectronic device of the embodiment in the present disclosure;

FIGS. 2A to 2F illustrate a process flow of a method of fabricating an optoelectronic device of another embodiment in the present disclosure;

FIGS. 3A to 3C illustrate the cross-sectional view of the structure of the embodiment in the present disclosure;

FIGS. 4A to 4C illustrate scanning electron microscope (SEM) pictures of the embodiment in the present disclosure.

### DETAILED DESCRIPTION OF THE PREFERRED EMBODIMENTS

Reference is made in detail to the preferred embodiments of the present application, examples of which are illustrated in the accompanying drawings. Wherever possible, the same reference numbers are used in the drawings and the description to refer to the same or like parts.

The present disclosure describes an optoelectronic device and a method of fabricating the optoelectronic device. In order to have a thorough understanding of the present disclosure, please refer to the following description and the illustrations.

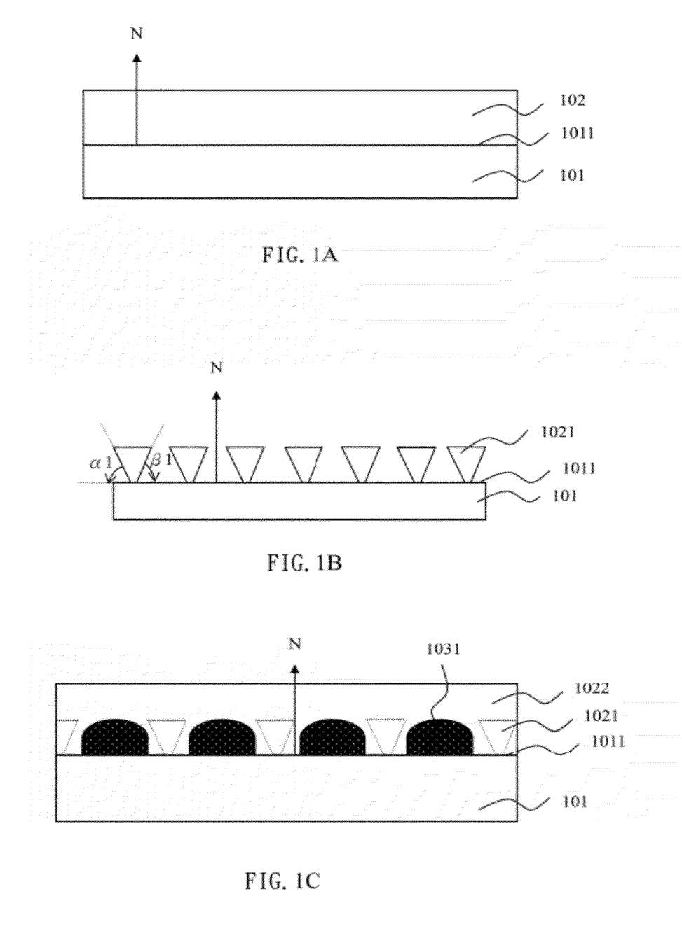

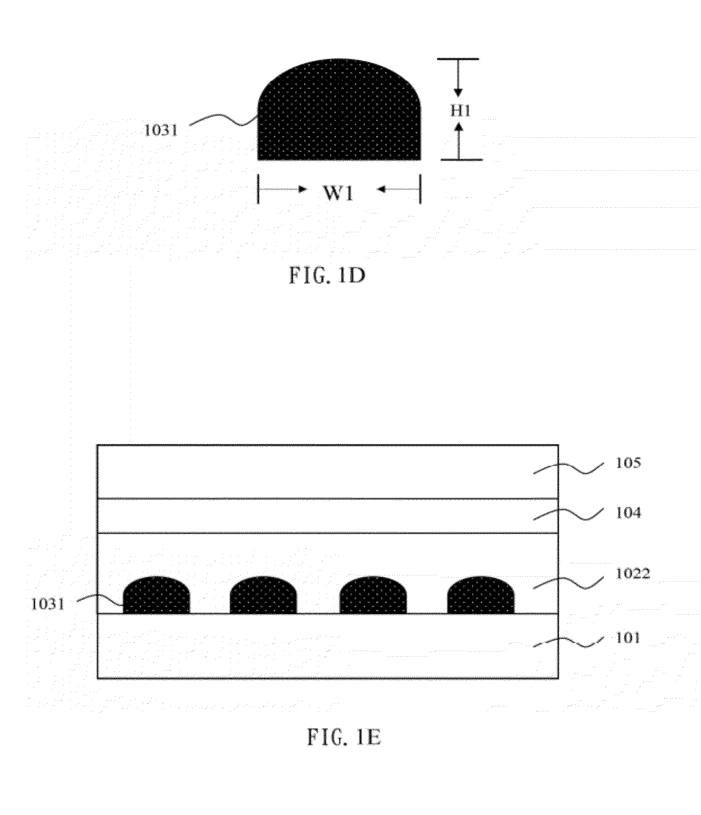

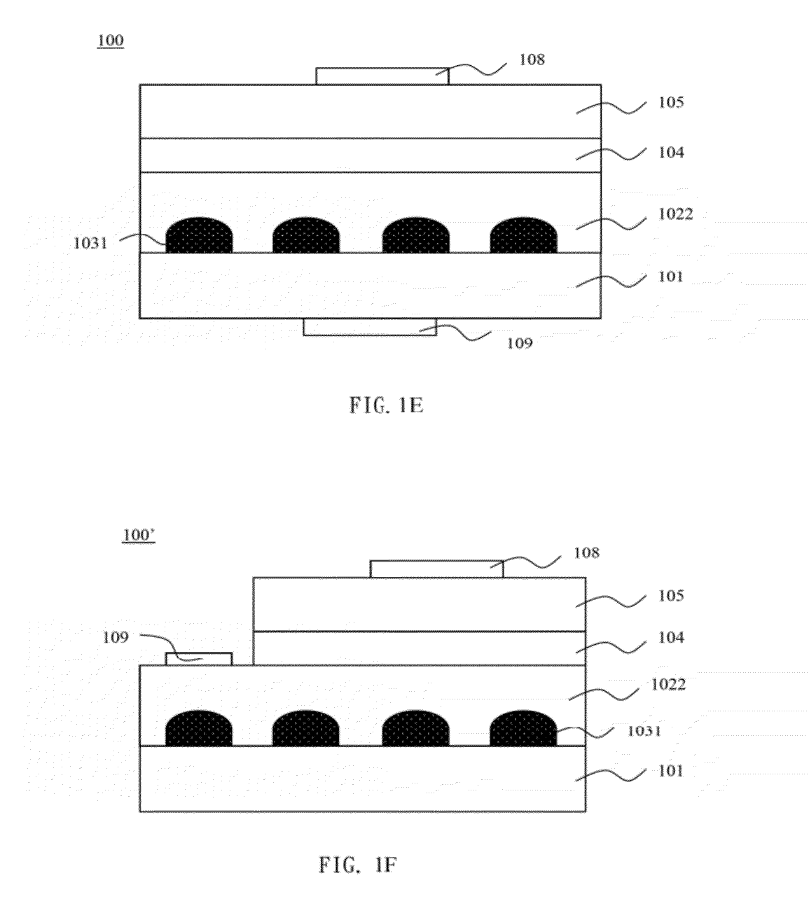

FIGS. 1A to 1E illustrate a process flow of the method of fabricating the optoelectronic device of the first embodiment of the present disclosure. FIG. 1A shows a substrate 101 having a normal direction N of a first major surface 1011. A first semiconductor layer 102 is formed on the first surface 1011 of the substrate 101.

As FIG. 1B shows, the first semiconductor layer 102 is etched to form a plurality of the first semiconductor rods 1021 on the first surface 1011 of the substrate 101 wherein the sidewalls of the plurality of the first semiconductor rods 1021 is not perpendicular to the first surface 1011 of the substrate 101. In one embodiment, the two sidewalls of the plurality of the first semiconductor rods 1021 and the first surface 1011 of the substrate 101 can form two angles α1 and β1 wherein the α1 can be 20°-75°, and the β1 can be 20°-75°. In one embodiment, the average width of the first semiconductor rods 1021 can be 0.5 μm-10 μm, and the average distance between the first semiconductor rods 1021 can be 0.5 μm-10 μm.

Following, as FIG. 1C shows, a second semiconductor 1022 is formed on the first surface 1011 of the substrate 101 wherein the second semiconductor 1022 is formed by the method of Epitaxial Lateral Overgrowth (ELOG). During the growing of the second semiconductor 1022, at least one first hollow component 1031 such as pore, void, bore, pinhole, and cavity is formed between the two adjacent first semiconductor rods 1021 and the first surface 1011 of the substrate 101.

As FIG. 1D shows, the cross-sectional view of the first hollow component 1031 projected completely on the normal direction N of the substrate 101 is a bell shape wherein the first hollow component 1031 having a width W1 and a height H1 that the width W1 of the first hollow component 1031 is defined as the largest size of the first hollow component 1031 perpendicular to the normal direction N of the substrate 101 and the height H1 of the first hollow component 1031 is defined as the largest size of the first hollow component 1031 parallel with the normal direction N of the substrate 101 and the height H1 is smaller than the width W1 of the first hollow component 1031. The width W1 of the first hollow component 1031 can be 0.5 μm-10 μm, 1 μm-10 μm, 2 μm-10 μm, 3 μm-10 μm, 4 μm-10 μm, 5 μm-10 μm, 6 μm-10 μm, 7 μm-10 μm, 8 μm-10 μm, or 9 μm-10 μm. In another embodiment of this application, the ratio of the height H1 and the width W1 of the first hollow component 1031 is smaller than 2/3. In one embodiment, the height H1 of the first hollow component 1031 varies along with a first direction perpendicular to the normal direction N and/or the width W1 of the first hollow component 1031 varies along with a second direction parallel with the normal direction N.

In another embodiment, a plurality of the first hollow components 1031 is formed. In one embodiment, at least two first hollow components 1031 can link into a mesh or porous structure. Besides, because the plurality of the first semiconductor rods 1021 can be a regular array structure, the plurality of the first hollow components 1031 can be a regular array structure wherein the average height Hₓ is smaller than the average width Wₓ of the plurality of the first hollow components 1031. The average width Wₓ of the first hollow component 1031 can be 0.5 μm-10 μm, 1 μm-10 μm, 2 μm-10 μm, 3 μm-10 μm, 4 μm-10 μm, 5 μm-10 μm, 6 μm-10 μm, 7 μm-10 μm, 8 μm-10 μm, or 9 μm-10 μm. In one embodiment, the ratio of the average height Hₓ and the average width Wₓ of the first hollow components 1031 is smaller than 2/3. In one embodiment, the average distance between any two of the first hollow components 1031 can be 0.5 μm-10 μm, 1 μm-10 μm, 2 μm-10 μm, 3 μm-10 μm, 4 μm-10 μm, 5 μm-10 μm, 6 μm-10 μm, 7 μm-10 μm, 8 μm-10 μm, or 9 μm-10 μm.

The porosity φ of the plurality of the first hollow components 1031 is defined as the total volume of the first hollow components Vᵥ divided by the overall volume V_{T} of the total volume of the first hollow component and the second semiconductor layer 1022

$$( φ = \frac{{V}_{V}}{{V}_{T}} ) .$$

In this embodiment, the porosity φ can be 5%-90%, 10%-90%, 20%-90%, 30%-90%, 40%-90%, 50%-90%, 60%-90%, 70%-90% or 80%-90%.

Following, as FIG. 1E shows, an active layer 104, and a third semiconductor layer 105 are formed on the second semiconductor layer 1022 subsequently.

Finally, as shown in FIG. 1F, two electrodes 108, 109 are formed on the third semiconductor layer 105 and the substrate 101 respectively to form a perpendicular type optoelectronic device 100.

In one embodiment, as shown in FIG. 1G, partial of the active layer 104 and the third semiconductor layer 105 are etched to expose partial of the second semiconductor layer 1022. Two electrodes 108, 109 are formed on the third semiconductor layer 105 and the second semiconductor layer 1022 respectively to form a horizontal type optoelectronic device 100′. The material of the electrode 108, 109 can be Cr, Ti, Ni, Pt, Cu, Au, Al, or Ag.

In one embodiment, the optoelectronic device 100′ can be bonded on a submount to form a flip-chip structure.

Each of the first hollow components 1031 inside the second semiconductor layer 1022 has a refractive index. Because of the difference of the refractive index of the first hollow component 1031 and the second semiconductor layer 1022, for example, the refractive index of the second semiconductor layer 1022 is 2-3, and the refractive index of air is 1 so the light transmitting into the first hollow component 1031 changes its emitting direction to outside the optoelectronic device and increases the light emitting efficiency. Besides, the first hollow component 1031 can be a scattering center to change the direction of the photon and decrease the total reflection. By increasing the porosity of the first hollow component 1031, the effect mentioned above is increasing.

Specifically speaking, the optoelectronic device 100, 100′ can be a light-emitting diode (LED), a laser diode (LD), a photoresister, an infared emitter, an organic light-emitting diode, a liquid crystal display, a solar cell, or a photo diode.

The material of the substrate 101 can be a conductive substrate, a non-conductive substrate, transparent or non-transparent substrate. The material of the conductive substrate can be germanium (Ge), gallium arsenide (GaAs), indium phosphide (InP), silicon carbide (SiC), silicon (Si), lithium aluminium oxide (LiAlO₂), zinc oxide (ZnO), gallium nitride (GaN), aluminum nitride (AlN), and metal. The transparent substrate can be sapphire, lithium aluminium oxide (LiAlO₂), zinc oxide (ZnO), gallium nitride (GaN), aluminum nitride (AlN), glass, diamond, CVD diamond, diamond-like carbon (DLC), spinel (MgAl₂O₄), aluminium oxide (Al₂O₃), silicon oxide (SiOₓ), and Lithium Dioxogallate (LiGaO₂).

In accordance with the embodiments in the application, the second semiconductor layer 1022 and the third semiconductor layer 105 are two single-layer structures or two multiple layers structure (“multiple layers” means two or more than two layers) having different electrical properties, polarities, dopants for providing electrons or holes respectively. If the first conductivity type layer 103 and the second semiconductor layer 1022 and the third semiconductor layer 105 are composed of the semiconductor materials, the conductivity type can be any two of p-type, n-type, and i-type. The active layer 104 disposed between the second semiconductor layer 1022 and the third semiconductor layer 105 is a region where the light energy and the electrical energy could transfer or could be induced to transfer. The device transferring the electrical energy to the light energy can be a light-emitting diode, a liquid crystal display, or an organic light-emitting diode; the device transferring the light energy to the electrical energy can be a solar cell or an optoelectronic diode.

In another embodiment of this application, the optoelectronic device 100, 100′ is a light emitting device. The light emission spectrum after transformation can be adjusted by changing the physical or chemical arrangement of one layer or more layers in the semiconductor system. The material of the semiconductor layer can be AlGaInP, AlGaInN, or ZnO. The structure of the active layer 104 can be a single heterostructure (SH), a double heterostructure (DH), a double-side double heterostructure (DDH), or a multi-quantum well (MQW). Besides, the wavelength of the emitted light could also be adjusted by changing the number of the pairs of the quantum well for a MQW structure.

In one embodiment of this application, a buffer layer (not shown) could be optionally formed between the substrate 101 and the second semiconductor layer 1022. The buffer layer between two material systems can be used as a buffer system. For the structure of the light-emitting diode, the buffer layer is used to reduce the lattice mismatch between two material systems. On the other hand, the buffer layer could also be a single layer, multiple layers, or a structure to combine two materials or two separated structures where the material of the buffer layer can be organic, inorganic, metal, semiconductor and so on, and the function of the buffer layer can be as a reflection layer, a heat conduction layer, an electrical conduction layer, an ohmic contact layer, an anti-deformation layer, a stress release layer, a stress adjustment layer, a bonding layer, a wavelength converting layer, a mechanical fixing structure and so on. The material of the buffer layer can be AlN, GaN, or other suitable materials. The fabricating method of the buffer layer can be sputter or atomic layer deposition (ALD).

A contact layer (not shown) can also be optionally formed on the third semiconductor layer 105. The contact layer is disposed on the side of the third semiconductor layer 105 away from the active layer 104. Specifically speaking, the contact layer could be an optical layer, an electrical layer or the combination of the two. An optical layer can change the electromagnetic radiation or the light from or entering the active layer 104. The term “change” here means to change at least one optical property of the electromagnetic radiation or the light. The abovementioned property includes but is not limited to frequency, wavelength, intensity, flux, efficiency, color temperature, rendering index, light field, and angle of view. An electrical layer can change or be induced to change the value, density, or distribution of at least one of the voltage, resistance, current, or capacitance between any pair of the opposite sides of the contact layer. The composition material of the contact layer includes at least one of oxide, conductive oxide, transparent oxide, oxide with 50% or higher transmittance, metal, relatively transparent metal, metal with 50% or higher transmittance, organic material, inorganic material, fluorescent material, phosphorescent material, ceramic, semiconductor, doped semiconductor, and undoped semiconductor. In certain applications, the material of the contact layer is at least one of indium tin oxide (ITO), cadmium tin oxide (CTO), antimony tin oxide, indium zinc oxide, zinc aluminum oxide, and zinc tin oxide. If the material is relatively transparent metal, the thickness is about 0.005 μm-0.6 μm.

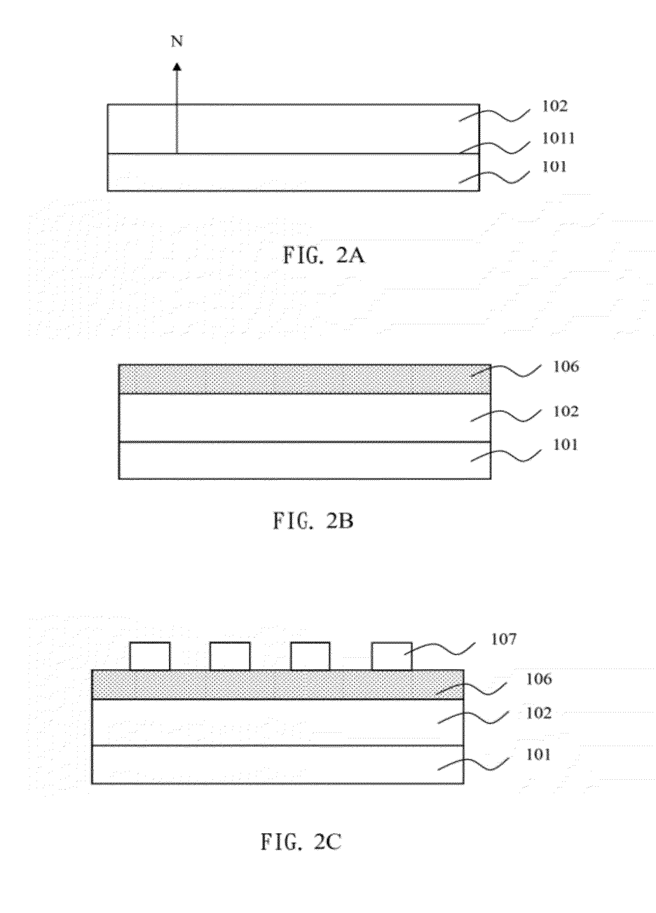

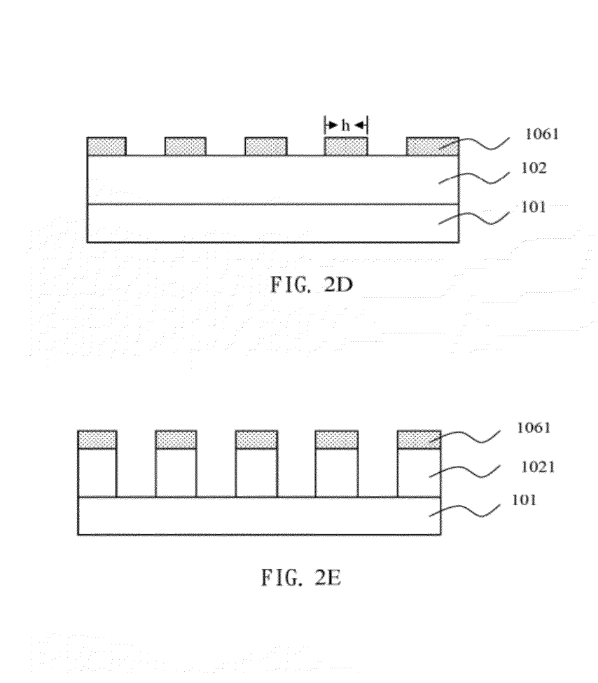

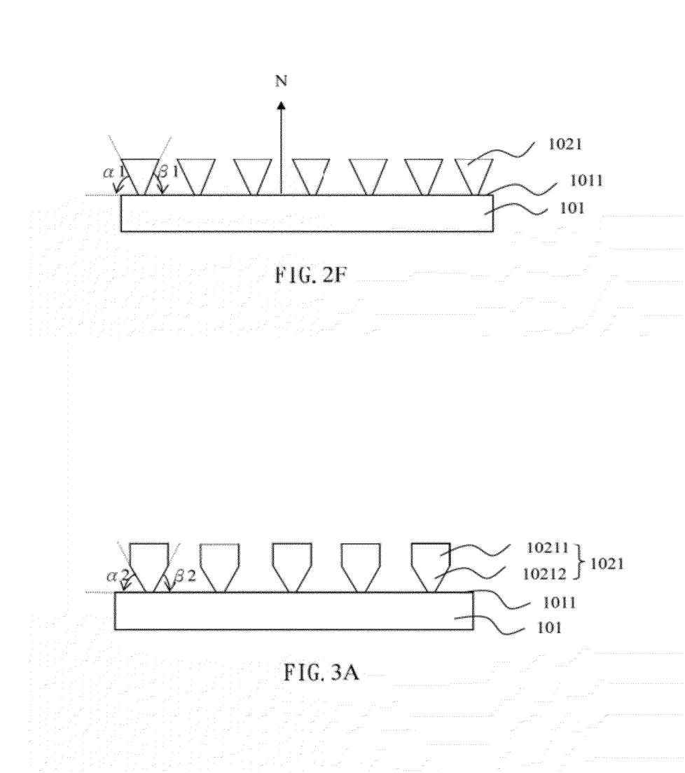

FIG. 2A-2F schematically illustrate a fabricating process of etching the first semiconductor layer 102 into the plurality of the first semiconductor rods 1021 in the first embodiment of this application. As FIG. 2A shows, a first semiconductor layer 102 is formed on the first surface 1011 of the substrate 101. As FIG. 2B shows, an anti-etching layer 106 is formed on the first semiconductor layer 102, and the material of the anti-etching layer 106 can be SiO₂.

Following, as FIGS. 2C-2D shows, a non-continuous photoresist layer 107 is formed on the anti-etching layer 106 and the anti-etching layer 106 can be formed into a patterned anti-etching layer 1061 by photolithography method. In one embodiment of this application, the patterned anti-etching layer 1061 can be a regular array. The average width h can be 0.5 μm-10 μm and the average distance can be 0.5 μm-10 μm.

As FIG. 2E shows, an etching process is performed. In the etching process, the patterned anti-etching layer 1061 is used as a mask for etching the first semiconductor layer 102. The etching process can be an anisotropic etching, for example, inductively-coupled plasma reactive ion etching (ICP-RIE) to etch the exposed first semiconductor layer 102 and formed a plurality of the first semiconductor rods 1021. In one embodiment, the average width of the plurality of first semiconductor rods 1021 can be 0.5 μm-10 μm and the average distance of any two of the first semiconductor rods 1021 can be 0.5 μm-10 μm.

Finally, a wet etching is performed on the first semiconductor rods 1021. In one embodiment, an anisotropic wet etching is performed with an aqueous solution of at least one of H₂SO₄, H₃PO₄, H₂C₂O₄, HCl, KOH, and NaOH, ethylene glycol solution, or their mixture. The sidewalls of the plurality of the first semiconductor rods 1021 are not perpendicular to the first surface 1011 of the substrate 101 because of the anisotropic etching. In other words, by the different etching rate of the etching solution to etch the different crystal structure or crystal quality, the corresponding scale and sidewall slope of the plurality of the first semiconductor rods 1021 can be defined. In one embodiment, the two sidewalls of the first semiconductor rods 1021 and the first surface 1011 of the substrate 101 can form two angles α1 and β1 wherein the al can be 20°-75°, and the β1 can be 20°-75°.

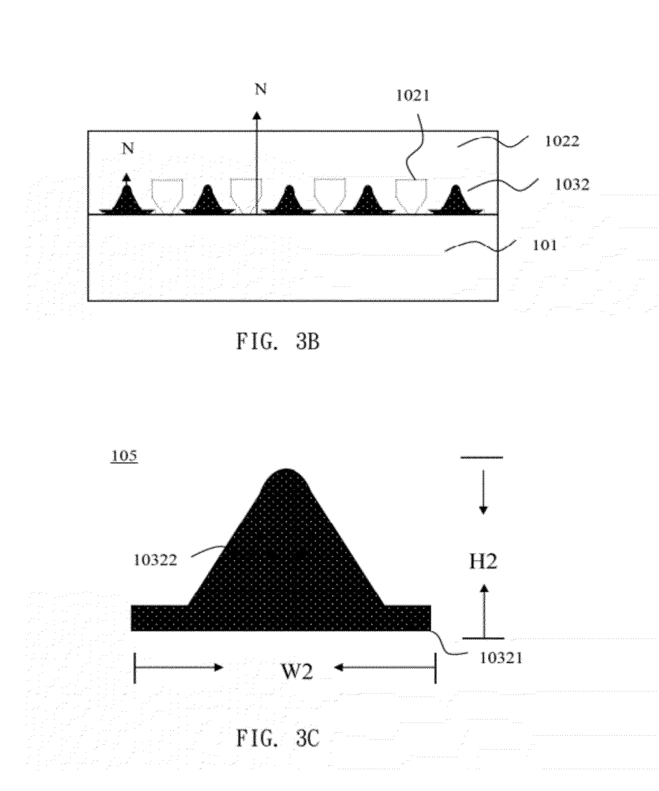

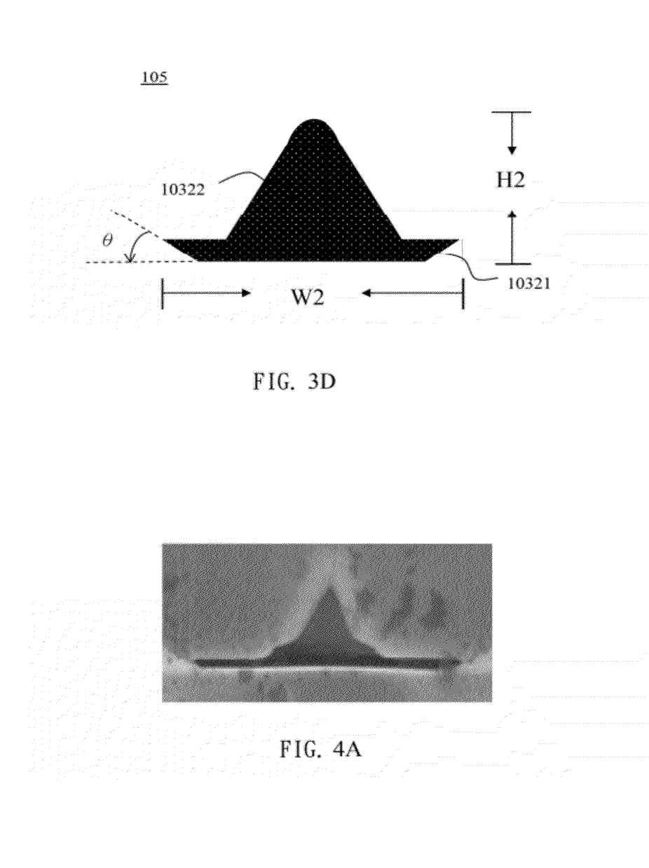

FIGS. 3A-3D illustrate the another embodiment of this application. In this embodiment, by adjusting the etching process mentioned in the FIGS. 2E-2F, the hollow components with different shapes can be formed. The other process of this embodiment is the same with the first embodiment described above.

As FIG. 3A shows, at least one of the plurality of the first semiconductor rods 1021 have a first portion of the sidewall 10211 which is perpendicular to the first surface 1011 of the substrate 101 and a second portion of the sidewall 10212 which is not perpendicular to the first surface 1011 of the substrate 101. In this embodiment, the second portion of the sidewall 10212 of the first semiconductor rod 1021 and the first surface 1011 of the substrate 101 can form two angle α1 and β1 wherein the α1 can be 20°-75°, and the β1 can be 20°-75°. The average width of the plurality of first semiconductor rods 1021 can be 0.5 μm-10 μm and the average distance of any two of the first semiconductor rods 1021 can be 0.5 μm-10 μm.

Following, as FIG. 3B shows, by the process mentioned in the first embodiment, a second semiconductor layer 1022 is formed to cover at least one second hollow component 1032 formed between two adjacent first semiconductor rods 1021 and the substrate 101.

As FIGS. 3C-3D shows, the cross-sectional view of the second hollow component 1032 projected completely on the normal direction N of the substrate 101 is a wizard's hat shape having a bottom section 10321 in a substantially disk shape and an upper section 10322 in a substantially cone shape. The bottom section 10321 having a length direction parallel with the surface of the substrate 101 and a height H2 parallel with the normal direction N, wherein the height H2 including the total height of the upper section 10321 and the bottom section 10322. The height H2 is the largest size of the second hollow component 1032 parallel with the normal direction N, and the bottom section 10321 of the second hollow component 1032 having a width (the width of the length direction) W2 defined as the largest size of the second hollow component 1032 perpendicular to the normal direction N of the substrate 101. In one embodiment, the height H2 of the second hollow component 1032 is smaller than the width W2 of the second hollow component 1032. The width W2 of the second hollow component 1032 can be 0.5 μm-10 μm, 1 μm-10 μm, 2 μm-10 μm, 3 μm-10 μm, 4 μm-10 μm, 5 μm-10 μm, 6 μm-10 μm, 7 μm-10 μm, 8 μm-10 μm, or 9 μm-10 μm. In another embodiment of this application, the ratio of the height H2 and the width W2 of the second hollow component 1032 is smaller than 2/3. In one embodiment, the height H2 of the second hollow component 1032 varies along with a first direction perpendicular to the normal direction N and/or the width W2 of the second hollow component 1032 varies along with a second direction parallel with the normal direction N.

In the embodiment, the cross-sectional view of the upper section 10322 can be substantially in a cone shape, in other words, the width of the upper section is decreased from the lower side closed to the substrate 101 to the upper side away from the substrate 101, and the top end of the upper section 10322 can be an apical, arc, or ball shape. Besides, in top-view the upper section 10332 is inside the bottom section 10321.

In another embodiment, as FIG. 3D shows, an angle θ forms between the edge of the bottom section 10321 in the length direction and the surface 1011 of the substrate 101 wherein the angle θ can be 20°-75°.

In another embodiment, a plurality of the second hollow components 1032 is formed between the two adjacent first semiconductor rods 1021 and the substrate 101. In one embodiment, at least two second hollow components 1032 can link into a mesh or porous structure. Besides, because the plurality of the first semiconductor rods 1021 can be a regular array structure, the plurality of the second hollow components 1032 can be a regular array structure wherein the average height H2ₓ is smaller than the average width W2ₓ of the plurality of the second hollow components 1032. The average width W2ₓ of the second hollow components 1032 can be 0.5 μm-10 μm, 1 μm-10 μm, 2 μm-10 μm, 3 μm-10 μm, 4 μm-10 μm, 5 μm-10 μm, 6 μm-10 μm, 7 μm-10 μm, 8 μm-10 μm, or 9 μm-10 μm. In one embodiment, the ratio of the average height H2ₓ and the average width W2ₓ of the second hollow components 1032 is smaller than 2/3. In one embodiment, the average distance between any two of the second hollow components 1032 can be 0.5 μm-10 μm, 1 μm-10 μm, 2 μm-10 μm, 3 μm-10 μm, 4 μm-10 μm, 5 μm-10 μm, 6 μm-10 μm, 7 μm-10 μm, 8 μm-10 μm, or 9 μm-10 μm.

The porosity φ of the plurality of the second hollow components 1032 is defined as the total volume of the second hollow components Vᵥ divided by the overall volume V_{T} of the total volume of the second hollow components 1032 and the second semiconductor layer 1022

$$( φ = \frac{{V}_{V}}{{V}_{T}} ) .$$

In this embodiment, the porosity φ can be 5%-90%, 10%-90%, 20%-90%, 30%-90%, 40%-90%, 50%-90%, 60%-90%, 70%-90% or 80%-90%.

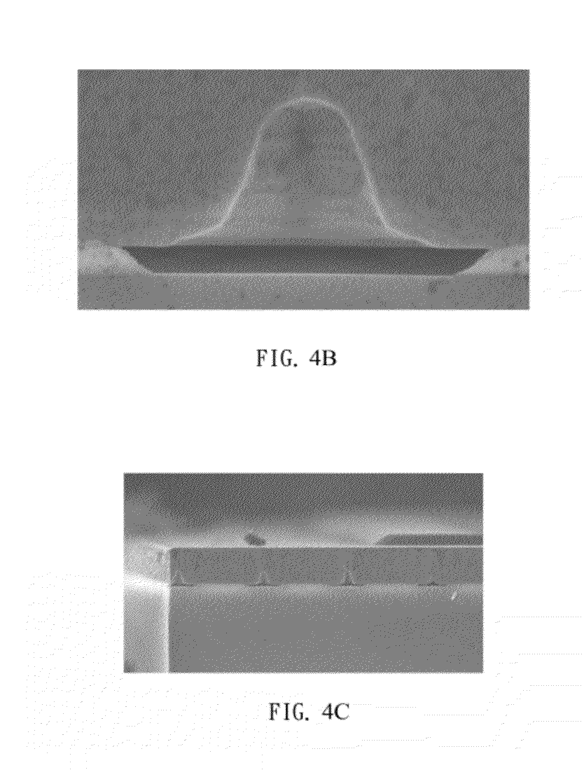

FIGS. 4A-4C illustrate scanning electron microscope (SEM) pictures of the embodiment of the present disclosure. As FIG. 4A shows, the top end of the upper section 10322 of the second hollow component 1032 can be an apical shape. As FIG. 4B shows, the top end of the upper section 10322 of the second hollow component 1032 can be an arc shape. As FIG. 4C shows, the plurality of the second hollow components 1032 can be a regular array.

It will be apparent to those having ordinary skill in the art that various modifications and variations can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

Although the drawings and the illustrations above are corresponding to the specific embodiments individually, the element, the practicing method, the designing principle, and the technical theory can be referred, exchanged, incorporated, collocated, coordinated except they are conflicted, incompatible, or hard to be put into practice together.

Although the present application has been explained above, it is not the limitation of the range, the sequence in practice, the material in practice, or the method in practice. Any modification or decoration for present application is not detached from the spirit and the range of such.

What is claimed is:

1. An optoelectronic device, comprising:
a substrate having a surface and a normal direction perpendicular to the surface;
a first semiconductor layer formed on the surface of the substrate; and
at least one hollow component formed between the first semiconductor layer and the surface of the substrate wherein a height of the hollow component varies along with a first direction perpendicular to the normal direction and/or a width of the hollow component varies along with a second direction parallel with the normal direction.

2. The optoelectronic device of claim 1, wherein the width of the hollow component is further defined as the largest size of the hollow component perpendicular to the normal direction of the substrate and the height of the hollow component is further defined as the largest size of the hollow component parallel with the normal direction of the substrate, and the height is smaller than the width.

3. The optoelectronic device of claim 1, wherein the cross-sectional view of the hollow component is a bell shape or wizard's hat shape.

4. The optoelectronic device of claim 1, wherein the width of at least one of the hollow component is 0.5 μm-10 μm and/or the ratio of the height and the width of at least one of the hollow component is smaller than 2/3.

5. The optoelectronic device of claim 1, wherein a plurality of the hollow components is formed between the first semiconductor layer and the substrate and at least two hollow components can link into a mesh or porous structure; or the plurality of the hollow components can be formed as a regular array and the average distance of the hollow components can be 0.5 μm-10 μm and the porosity of the hollow components can be 5-90%.

6. The optoelectronic device of claim 1, further comprising an active layer and a second conductivity semiconductor layer formed on the first semiconductor layer wherein the material of the first semiconductor layer, the active layer, or the second semiconductor layer contains at least one element selected from the group consisting of Al, Ga, In, As, P, and N.

7. The optoelectronic device of claim 3, wherein the cross-sectional view of the hollow component is a wizard's hat shape having a bottom section with disk shape and a upper section with cone shape wherein the top end of the upper section be an apical, arc, or ball shape, and the upper section is inside the bottom section in top-view.

8. The optoelectronic device of claim 7, wherein the bottom section having a length direction parallel with the surface of the substrate and the width of the bottom section in the length direction can be 0.5 μm-10 μm.

9. The optoelectronic device of claim 7, further comprising an angle θ forms between the edge of the bottom section in the length direction and the surface of the substrate wherein the angle θ can be 20°-75°.

10. A method of fabricating an optoelectronic device, comprising:
providing a substrate having a surface and a normal direction perpendicular to the surface;
forming a first semiconductor layer on the surface of the substrate;
patterning the first semiconductor layer;
forming a second semiconductor layer on the substrate and cover the patterned first semiconductor layer; and
forming at least one hollow component formed between the first semiconductor layer and the surface of the substrate wherein a height of the hollow component varies along with a first direction perpendicular to the normal direction and/or a width of the hollow component varies along with a second direction parallel with the normal direction.

11. The method of fabricating an optoelectronic device of claim 10, wherein the width of the hollow component is further defined as the largest size of the hollow component perpendicular to the normal direction of the substrate and the height of the hollow component is further defined as the largest size of the hollow component parallel with the normal direction of the substrate, and the height is smaller than the width.

12. The method of fabricating an optoelectronic device of claim 10,
wherein the method to patterning the first semiconductor comprising:
forming an anti-etching layer on the first semiconductor layer;
forming a plurality of photoresist layers on the anti-etching layer;
patterning the anti-etching layer; and
using the patterned anti-etching layer to anisotropic etching the first semiconductor layer.

13. The method of fabricating an optoelectronic device of claim 12, wherein the anisotropic etching is performed with an aqueous solution of at least one of H₂SO₄, H₃PO₄, H₂C₂O₄, HCl, KOH, and NaOH, ethylene glycol solution, or their mixture.

14. The method of fabricating an optoelectronic device of claim 10, wherein the cross-sectional view of the hollow component is bell shape or wizard's hat shape.

15. The method of fabricating an optoelectronic device of claim 10, wherein the width of the hollow component is 0.5 μm-10 μm and/or the ratio of the height and the width of the hollow component is smaller than 2/3.

16. The method of fabricating an optoelectronic device of claim 10, wherein a plurality of the hollow components is formed between the first semiconductor layer and the substrate and at least two hollow components can link into a mesh or porous structure; or the plurality of the hollow components can be formed as a regular array and the average distance of the hollow components can be 0.5 μm-10 μm and the porosity of the hollow components can be 5-90%.

17. The method of fabricating an optoelectronic device of claim 10, further comprising an active layer and a third conductivity semiconductor layer formed on the second semiconductor layer wherein the material of the first semiconductor layer, the second semiconductor layer, the active layer or the third semiconductor layer contains at least one element selected from the group consisting of Al, Ga, In, As, P, and N.

18. The method of fabricating an optoelectronic device of claim 14, wherein the cross-sectional view of the hollow component is wizard's hat shape having a bottom section with disk shape and a upper section with cone shape wherein the top end of the upper section be an apical, arc or ball shape, and the upper section is inside the bottom section in top-view.

19. The method of fabricating an optoelectronic device of claim 18, wherein the bottom section having a length direction parallel with the surface of the substrate and the width of the bottom section in the length direction can be 0.5 μm-10 μm.

20. The method of fabricating an optoelectronic device of claim 18, further comprising an angle θ forms between the edge of the bottom section in the length direction and the surface of the substrate wherein the angle θ can be 20°-75°.
